(19) United States
(12) Patent Application Publication
(10) Pub. No.: US 2026/0178083 A1
(43) Pub. Date: Jun. 25, 2026

(54) DISPLAY DEVICE

(71) Applicant: LG Display Co., Ltd., Seoul (KR)

(72) Inventors: ChangHyun SONG, Paju-si (KR); Seunghwan KIM, Paju-si (KR); MinJoo KIM, Paju-si (KR)

(73) Assignee: LG Display Co., Ltd., Seoul (KR)

(21) Appl. No.: 19/223,996

(22) Filed: May 30, 2025

(30) Foreign Application Priority Data
Dec. 24, 2024 (KR) 10-2024-0195717

(51) Int. Cl. G06F 1/16; H10K 59/80; H10K 77/10; H10K 102/00

(52) U.S. Cl. CPC G06F 1/1652; H10K 59/8722; H10K 77/111; H10K 2102/311

(57) ABSTRACT

Embodiments of the disclosure may provide a display device comprising a display panel including a bending area and a non-bending area, and a support structure disposed beneath the display panel. The support structure includes a first body portion overlapping the bending area and a second body portion overlapping the non-bending area. The thickness of the first body portion is smaller than a thickness of the second body portion. This structure may reduce tensile stress in the bending area and help prevent cracks in the display panel during bending, thereby improving mechanical durability and flexibility.

### CROSS-REFERENCE TO RELATED APPLICATION

This application claims priority from Korean Patent Application No. 10-2024-0195717, filed on Dec. 24, 2024, which is hereby incorporated by reference for all purposes as if fully set forth herein.

### BACKGROUND

### Technical Field

Embodiments of the disclosure relate to a display device.

### Description of Related Art

With the advent of the information age, the display industry—responsible for visually representing electrical information signals—has rapidly advanced. In response, a wide variety of display devices offering superior performance in terms of thinness, lightness, and low power consumption have been developed.

Specific examples of such display devices include liquid crystal display devices (LCDs), plasma display panel devices (PDPs), field emission display devices (FEDs), organic light emitting display devices (OLEDs) and the like.

### BRIEF SUMMARY

Recently, to enhance the aesthetic appeal of display devices, edge portions of display panels have been bent to form curved surfaces. However, it has been recognized that the bending process can generate tensile stress in the edge areas of the panel, which may result in the formation of cracks.

The disclosure describes various embodiments of a display device structure that improves flexibility and mechanical durability. In one aspect, a support layer is formed to be thinner under the bending area and thicker under the non-bending area, thereby reducing tensile stress and reducing the risk of cracking during bending. The display panel also includes two base substrates, with a smaller lower substrate ending inside a larger upper substrate, allowing part of the upper substrate to remain exposed in the bending region to create additional space for curvature and reduce overall thickness.

The support may taper gradually toward the bending area through an inclined or concave shape, and a reinforcing layer can be added beneath the support to enhance structural strength. This reinforcement may cover only the non-bending region or extend across both bending and non-bending areas, with an adhesive layer optionally filling a recess formed during bending. The design supports OLED integration even in the curved edges, enabling extended display areas while maintaining durability and high resolution in the flat regions.

Example embodiments of the disclosure may provide a display device capable of preventing cracks from occurring on the upper portion of the display panel during bending, by forming the thickness of the bending area to be smaller than that of the non-bending area.

Example embodiments of the disclosure may provide a display device in which a space for bending is formed at the lower side of the display panel, by forming the length of a second base substrate, which constitutes the lower portion of the display panel, to be shorter than that of the first base substrate.

Example embodiments of the disclosure may provide a display device comprising a display panel including a bending area and a non-bending area and a support supporting a lower portion of the display panel and including a first body portion overlapping the bending area and a second body portion overlapping the non-bending area, wherein a thickness of the first body portion is smaller than a thickness of the second body portion.

According to embodiments of the disclosure, there may be provided a display device comprising a display panel including a bending area and a non-bending area, and a support supporting a lower portion of the display panel and including a first body portion overlapping the bending area and a second body portion overlapping the non-bending area, wherein the display panel includes a first base substrate, and a second base substrate disposed under the first base substrate, formed to be smaller than the first base substrate so that an end portion thereof is positioned inside the first base substrate.

Technical benefits of embodiments of the disclosure are not limited to those set forth herein, and other unmentioned benefits would be apparent to one of ordinary skill in the art from the following description.

According to embodiments of the disclosure, there may be provided a display device capable of preventing cracks from occurring on the upper portion of the display panel during bending, by forming the thickness of the bending area to be smaller than that of the non-bending area.

According to embodiments of the disclosure, there may be provided a display device in which a space for bending is formed at the lower side of the display panel, by forming the length of a second base substrate, which constitutes the lower portion of the display panel, to be shorter than that of the first base substrate.

According to embodiments of the disclosure, there may be provided a low-power display device by using OLEDs as light emitting elements.

The effects of the disclosure are not limited to the foregoing objects, and other effects will be apparent to one of ordinary skill in the art from the following detailed description.

### BRIEF DESCRIPTION OF THE SEVERAL VIEWS OF THE DRAWINGS

The disclosure will be more fully understood from the following detailed description and the accompanying drawings, which are provided for illustration only and are not intended to limit the disclosure.

FIG. 1 is a perspective view illustrating a display device according to embodiments of the disclosure;

FIG. 2 is a view illustrating a configuration of a system of a display device according to embodiments of the disclosure;

FIG. 3 is a cross-sectional view taken along line A-A′ of FIG. 2;

FIG. 4 is an enlarged view illustrating a portion of FIG. 3;

FIG. 5 is a view illustrating a bent state of a display device according to an embodiment of the disclosure; and

FIG. 6 is a view illustrating a bent state of a display device according to another embodiment of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements, etc., but is used merely to distinguish the corresponding element from other elements.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

To elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

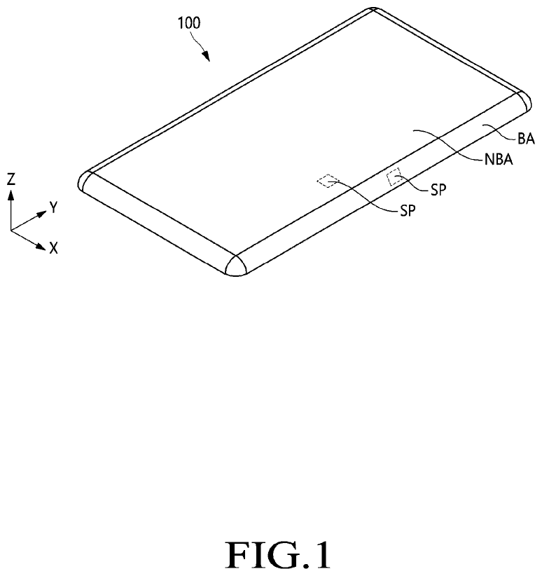

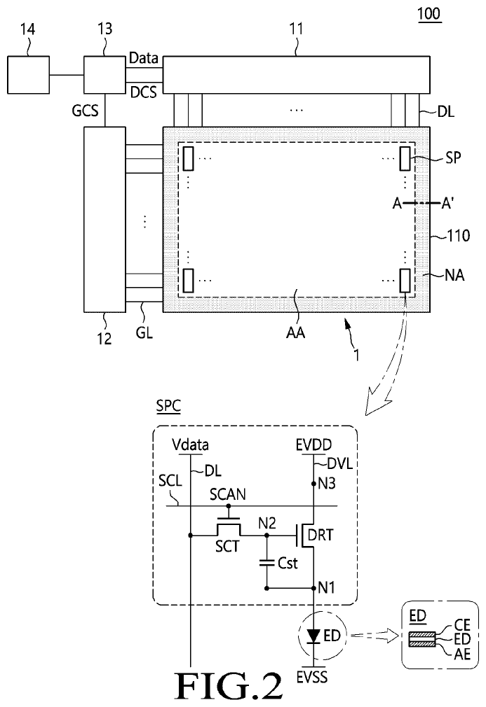

FIG. 1 is a perspective view illustrating a display device according to embodiments of the disclosure, and FIG. 2 is a view illustrating a system configuration of a display device according to embodiments of the disclosure.

Referring to FIGS. 1 and 2, a display driving system of a display device 100 may include a display panel 110 and display driving circuits for driving the display panel 110.

The display panel 110 may include a display area AA in which images are displayed and a non-display area NA in which no image is displayed. The non-display area NA may be an outer area of the display area AA and may also be a bezel area. The whole or part of the non-display area NA may be an area visible from the front surface of the display device 100 or an area that is bent and not visible from the front surface of the display device 100.

The display panel 110 may include a non-bending area NBA and a bending area BA disposed outside the bending area BA to be bent. For example, the non-bending area NBA may be formed in a rectangular flat plate shape, and the bending area BA forming the edge portion around the non-bending area NBA may be bent with a preset curvature. The bending area BA may include a non-display area NA and a display area AA adjacent to the non-display area NA. In other words, an image may also be displayed in the bending area BA.

A bending area BA may be formed in all of the edge portions of the display panel 110. For example, when the display panel 110 is formed in a rectangular shape, the bending area BA may be formed in all of the four edge areas. The bending area BA is not limited to the illustrated examples, and bending areas BA may be formed on two opposite sides of the length direction. In other words, the bending area BA may be formed to be elongated in the Y-axis direction on the drawings to be formed at left and right edge portions of the display panel 110.

The display panel 110 may include a plurality of subpixels SP disposed on a base substrate 111 for image display. The display panel 110 may include a plurality of signal lines to drive the plurality of subpixels SP. For example, the plurality of signal lines may include data lines DL, gate lines GL, driving voltage lines DVL, and the like.

Each of the plurality of data lines DL is disposed while extending in a first direction (e.g., a column direction or a row direction), and each of the plurality of gate lines GL is disposed while extending in a direction crossing the first direction.

The display driving circuits may include a data driving circuit 11 and a gate driving circuit 12 and may further include a controller 13 for controlling the data driving circuit 11 and the gate driving circuit 12.

The data driving circuit 11 may output data signals (also referred to as data voltages) corresponding to an image signal to the plurality of data lines DL. The gate driving circuit 12 may generate gate signals and output the gate signals to the plurality of gate lines GL. The controller 13 may convert the input image data input from an external host 14 to meet the data signal format used in the data driving circuit 11 and supply the converted image data to the data driving circuit 11.

The data driving circuit 11 may include one or more source driver integrated circuits. For example, each source driver integrated circuit may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit 12 may be connected to the display panel 110 by a tape automatic bonding (TAB) method, connected to a bonding pad of the display panel 110 by a COG or COP method, connected to the display panel 110 by a COF method, or may be formed in the non-display area NA of the display panel 110 by a gate in panel (GIP) method.

Referring to FIG. 2, in the display device 100 according to embodiments of the disclosure, the subpixel SP may include a light emitting element ED and a pixel driving circuit SPC for driving the light emitting element ED. The pixel driving circuit SPC may include a driving transistor DRT, a scan transistor SCT, and a storage capacitor Cst.

The driving transistor DRT may control a current flowing to the light emitting element ED to drive the light emitting element ED. The scan transistor SCT may transfer the data voltage Vdata to the second node N2 which is the gate node of the driving transistor DRT. The storage capacitor Cst may be configured to maintain a voltage for a predetermined period of time.

The light emitting element ED may include a first electrode AE, a second electrode CE, and a light emitting layer 170 positioned between the first electrode AE and the second electrode CE. The first electrode AE may be a pixel electrode involved in forming the light emitting element ED of each subpixel SP and may be electrically connected to the first node N1 of the driving transistor DRT. The second electrode CE may be a common electrode involved in forming the light emitting elements ED of all the subpixels SP, and a ground voltage EVSS may be applied thereto.

For example, the light emitting element ED may be an organic light emitting diode OLED, an inorganic light emitting diode (LED), or a quantum dot light emitting element, which is a self-luminous semiconductor crystal.

The driving transistor DRT is a transistor for driving the light emitting element ED, and may include a first node N1, a second node N2, and a third node N3. The first node N1 may be a source node or a drain node, and may be electrically connected to the first electrode AE of the light emitting element ED. The second node N2 is a gate node and may be electrically connected to the source node or drain node of the scan transistor SCT. The third node N3 may be a drain node or a source node, and may be electrically connected to a driving voltage line DVL that supplies the driving voltage EVDD. For convenience of description, in the example described below, the first node N1 may be a source node and the third node N3 may be a drain node.

The scan transistor SCT may switch the connection between the data line DL and the second node N2 of the driving transistor DRT. In response to the scan signal SCAN supplied from the scan line SCL which is a kind of the gate line GL, the scan transistor SCT may control connection between the second node N2 of the driving transistor DRT and a corresponding data line DL among the plurality of data lines DL.

The storage capacitor Cst may be configured between the first node N1 and second node N2 of the driving transistor DRT.

The structure of the subpixel SP illustrated in FIG. 2 is merely an example for description, and may further include one or more transistors, or one or more storage capacitors. The plurality of subpixels SP may have the same structure, or some of the plurality of subpixels SP may have a different structure. Each of the driving transistor DRT and the scan transistor SCT may be an n-type transistor or a p-type transistor.

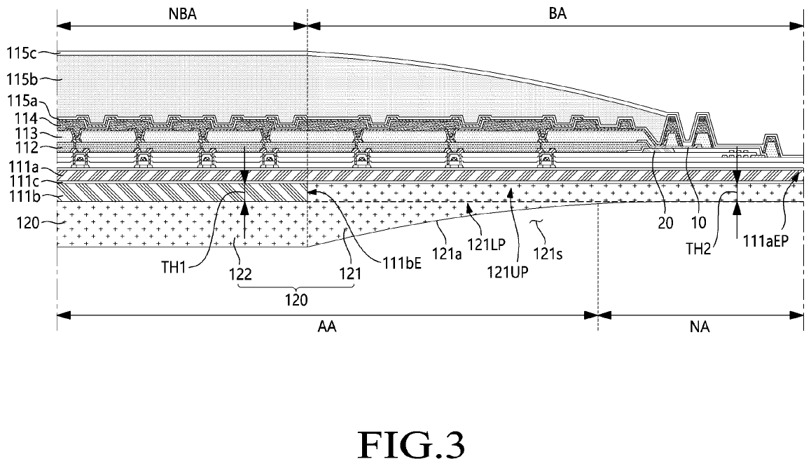

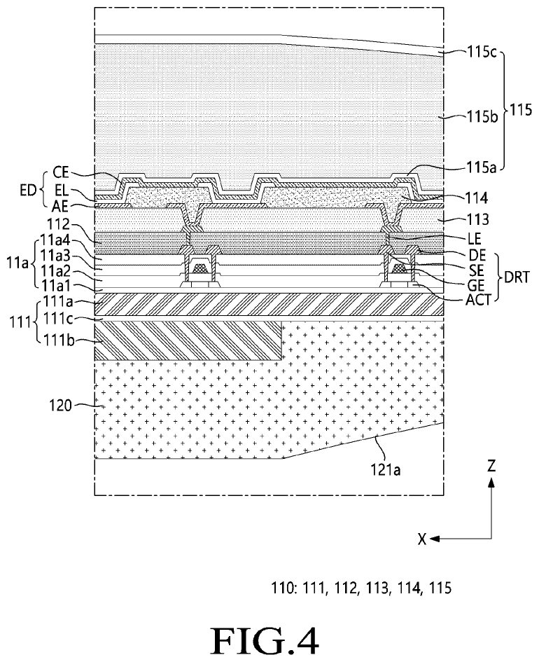

FIG. 3 is a cross-sectional view taken along line A-A′ of FIG. 2, and FIG. 4 is an enlarged view illustrating a portion of FIG. 3.

Referring to FIGS. 3 and 4, the display device 100 may include a display panel 110 and a support structure 120 (also referred to as ‘a support 120’).

On the display panel 110 where an image is implemented, a light emitting element ED for implementing an image, a circuit for driving the light emitting element ED, lines, and components may be disposed. For example, the display panel 110 may be applied to one selected from among a liquid crystal display (LCD) device, a field emission display (FED) device, an electroluminescence display (ELD) device, and an organic light emitting diode (OLED) display device. In embodiments of the disclosure, an OLED, which is a representative of a flexible display device capable of maintaining display performance even when bent like paper, may be applied.

OLED is a self-luminous device, and its lightweight and thin form factor is possible because it does not require a backlight, unlike liquid crystal displays, which are non-emissive. Furthermore, it offers superior viewing angles and contrast ratios compared to liquid crystal displays, is advantageous in terms of power consumption, can operate at low DC voltage, has a fast response time, is resistant to external impacts due to its solid internal components, and supports a wide operating temperature range. In particular, since the manufacturing process is simple, there is an advantage in that production costs may be decreased more than conventional liquid crystal displays.

The display panel 110 may include a bending area BA and a non-bending area NBA. For example, the bending area BA may include a subpixel SP in a portion adjacent to the non-bending area NBA. In other words, the bending area BA may also include a display area AA to display an image. In this case, the non-bending area NBA may be formed to have a higher resolution than the bending area BA. In other words, in the non-bending area NBA, the sub-pixels SP may be more densely disposed than in the bending area BA.

The support 120 reinforces the display panel 110, which has a thin profile, and may support the lower portion of the display panel 110. For example, the support 120 may be formed of a polymer material such as polymethyl methacrylate (PMMA), polycarbonate (PC), polyvinyl alcohol (PVA), acrylonitrile-butadiene-styrene (ABS), polyethylene terephthalate (PET), silicone, or polyurethane (PU).

The support 120 may include a first body portion 121 overlapping the bending area BA and a second body portion 122 overlapping the non-bending area NBA. The first body portion 121 and the second body portion 122 may be formed of the same material. For example, the first and second body portions 121 and 122 may be formed of a material selected from among polymethylmethacrylate (PMMA), polycarbonate (PC), polyvinyl alcohol (PVA), acrylonitrile-butadiene-styrene (ABS), polyethylene terephthalate (PET), silicone, and polyurethane (PU).

The thickness of the first body portion 121 may be smaller than the thickness of the second body portion 122. As the thickness of the first body 121 is smaller than that of the second body 122, it is possible to address the issues of cracking the display panel 110 during bending by reducing the tensile stress applied to the upper portion of the display panel 110 when bending the display panel 110 to form the bending area BA. In other words, when the thickness of the first body 121 is smaller than the thickness of the second body 122, an empty space 121s is formed at a lower portion of the first body 121 so that the display panel 110 may be easily bent, thereby preventing cracks from occurring on the upper portion of the display panel 110.

The support 120 may be formed so that the thickness of the first body portion 121 gradually decreases from the non-bending area NBA to the bending area BA. For example, the lower portion of the first body portion 121 may be formed in a curved shape concave toward the display panel 110. According to the shape, the first body portion 121 adjacent to the second body portion 122 may include an inclined surface 121a. In this case, the slope of the inclined surface 121a may be provided in a range of 30° to 90°. Since the thickness of the contact portion between the first body portion 121 and the second body portion 122 may be formed as large as possible by the inclined surface 121a, a space 121s for bending may be secured at the lower portion of the first body portion 121 and the display panel 110 may be stably supported through the support 120.

A support structure 120 may be disposed under a display panel 110 including a bending area BA and a non-bending area NBA. The support structure 120 may include a first body portion 121 overlapping the bending area BA in a plan view and a second body portion 122 overlapping the non-bending area NBA in a plan view.

The first body portion 121 may have an upper portion 121UP facing the display panel 110 and a lower portion 121LP opposite the upper portion 121UP. The lower portion 121LP of the first body portion 121 may be recessed toward the display panel 110 to form a bending space, such that the lower portion 121LP has a reduced thickness relative to the second body portion 122 in the bending area BA. For example, at the boundary between the non-bending area (NBA) and the bending area (BA), the thickness of the second body portion 122 is equal to the thickness of the lower portion 121LP of the first body portion 121. However, the thickness of the lower portion 121LP gradually decreases from the boundary toward the bending area BA. This recessed structure facilitates bending of the display panel while maintaining structural support.

The first and second body portions may be formed of the same material, such as polycarbonate, polymethyl methacrylate (PMMA), or other suitable polymers, and may be integrally or monolithically formed. As shown in FIG. 3, the thickness of the lower portion 121LP of the first body portion 121 may gradually decrease from the non-bending area toward the bending area, and may include an inclined or concave profile to aid in stress relief during bending.

The display panel 110 may include a base substrate 111, a first planarization layer 112, a second planarization layer 113, a bank layer 114, a light emitting element ED, and an encapsulation layer 115.

The base substrate 111 may be formed of two or more layers. For example, the base substrate 111 may include a first base substrate 111a, a second base substrate 111b, and an insulation layer 111c disposed between the first base substrate 111a and the second base substrate 111b.

The first base substrate 111a supports various components of the display panel 110 and may be formed of polyimide (PI). For example, the base substrate 111 may be disposed on the bending area BA and the non-bending area NBA.

The second base substrate 111b may be disposed under the first base substrate 111a, and may be formed to be smaller than the first base substrate 111a so that an end portion thereof may be disposed inside the first base substrate 111a. In other words, the second base substrate 111b may be formed to be smaller in the X-axis direction than the first base substrate 111a. For example, the end portion of the first base substrate 111a may overlap the non-display area NA, and the end portion of the second base substrate 111b may overlap the display area AA.

As the end portion of the second base substrate 111b is formed to be shorter than the end portion of the first base substrate 111a by the length of the bending area BA, a portion of the first base substrate 111a may be exposed in the bending area BA. Since the first body portion 121 may be disposed in the exposed space, the thickness of the display panel 110 is decreased in the bending area BA, so that a much lower space 121s for bending the display panel 110 may be secured.

Meanwhile, the thickness of the end portion of the first body portion 121 may be equal to or smaller than the thickness of the second base substrate 111b. Accordingly, bending of the display panel 110 may be facilitated by securing the lower space 121s to the greatest extent possible for bending, while stably maintaining the thickness of the support 120 positioned in the bending area BA.

Like the first base substrate 111a, the second base substrate 111b may be formed of polyimide (PI). Polyimide is a polymer with a relatively low degree of crystallization or mostly amorphous structure, and may be easily synthesized to make a thin film-type film, and has advantages such as transparency, heat resistance, and good mechanical properties. However, since polyimide has poor moisture barrier properties, an inorganic film layer 111c formed of an inorganic insulating material such as silicon nitride (SiNx) or silicon oxide SiOx may be disposed between the second base substrate 111b and the first base substrate 111a to enhance the moisture resistance of the base substrate 111. For example, the inorganic layer 111c may be disposed in the display area AA and the non-display area NA, and may cover the entire lower surface of the first base substrate 111a.

The display panel 110 may include a first base substrate 111a and a second base substrate 111b adjacent to the first base substrate 111a. The second base substrate 111b may be disposed between the first base substrate 111a and the support structure 120, and may terminate within the non-bending area NBA. The first base substrate 111a may extend continuously and contiguously from the non-bending area NBA into the bending area BA beyond the end of the second base substrate 111b, such that the end portion 111bE of the second base substrate 111b is positioned inward of the end portion 111aEP of the first base substrate 111a. The extension of the first base substrate 111a into the bending area BA allows for space to be formed between the first body portion 121 of the support structure 120 and the display panel 110 to accommodate bending.

In some embodiments, the thickness TH1 of the second base substrate 111b may be equal to or greater than the thickness TH2 of the upper portion 121UP of the first body portion 121 of the support structure 120, thereby ensuring that the structure beneath the non-bending area NBA remains mechanically robust, while the bending area remains flexible and reduced in thickness.

A plurality of insulation layers 11a for forming the driving transistor DRT may be formed on the base substrate 111. For example, the insulation layer 11a may include a first insulation layer 11a1, a second insulation layer 11a2, a third insulation layer 11a3, and a fourth insulation layer 11a4.

The first insulation layer 11a1 may enhance the adhesion between the layers formed thereabove and the base substrate 111, and may also prevent alkaline components from leaching out of the base substrate 111. The first insulation layer 11a1 may be referred to as a buffer layer. Although the first insulation layer 11a1 is formed as a single layer in the present embodiment, the first insulation layer 11a1 may be formed of a plurality of layers.

The driving transistor DRT may be disposed on the first insulation layer 11a1. For example, the driving transistor DRT may include an active layer ACT, a gate electrode GE, a source electrode SE, and a drain electrode DE.

The active layer ACT is a semiconductor layer and may be disposed on the first insulation layer 11a1. The active layer ACT may include a channel area, a source area, and a drain area. The channel area may overlap the gate electrode GE with the second insulation layer 11a2 interposed therebetween to form a channel area between the source electrode SE and the drain electrode DE. The source area may be electrically connected to the source electrode SE, and the drain area may be electrically connected to the drain electrode DE.

The gate electrode GE may be disposed on the second insulation layer 11a2, and may be covered by the third insulation layer 11a3. For example, the gate electrode GE may overlap the channel area of the active layer ACT with the second insulation layer 11a2 interposed therebetween. The gate electrode GE may be formed as a single layer or multiple layers composed of any one of molybdenum (Mo), aluminum (Al), chromium (Cr), gold (Au), titanium (Ti), nickel (Ni), neodymium (Nd), and copper (Cu), or an alloy thereof.

The source electrode SE may be disposed on the fourth insulation layer 11a4, and may penetrate the fourth insulation layer 11a4, the third insulation layer 11a3, and the second insulation layer 11a2 to be connected to the source area of the active layer ACT.

The drain electrode DE may be disposed on the fourth insulation layer 11a4 to face the source electrode SE, and may penetrate the fourth insulation layer 11a4, the third insulation layer 11a3, and the second insulation layer 11a2 to be connected to the drain area of the active layer ACT.

The first planarization layer 112 may cover the source electrode SE and the drain electrode DE on the fourth insulation layer 11a4. For example, the first planarization layer 112 may be formed of an organic material such as an acrylic resin, an epoxy resin, a phenolic resin, a polyamide resin, or a polyimide resin.

A connection electrode LE for connecting the light emitting element ED and the drain electrode DE may be disposed on the first planarization layer 112. For example, the first planarization layer 112 may include a contact hole for connecting the connection electrode LE and the source electrode SE.

The second planarization layer 113 may be formed of an organic material such as an acrylic resin, an epoxy resin, a phenolic resin, a polyamide resin, and a polyimide resin, and may cover the connection electrode LE on the first planarization layer 112. For example, the second planarization layer 113 may include a contact hole for connecting the first electrode AE and the connection electrode LE.

The bank layer 114 may partition the pixels and may be disposed on the second planarization layer 113. For example, the bank layer 114 may have an opening for exposing the first electrode AE in the display area AA.

The bank layer 114 may be formed of a material including a black pigment or the like, or an organic material such as benzocyclobutene resin, polyimide resin, acrylic resin, or photosensitive polymer, but embodiments of the disclosure are not limited thereto. When the bank layer 114 is formed of a material including a black pigment or a black dye, it may be a black bank. When the bank layer 114 is formed of a material including a black pigment or a black dye, light from the outside or light reflected from the outside may be blocked, and thus the luminance of the display device 100 may be further enhanced.

The light emitting element ED may include a first electrode AE that is an anode electrode, an emission layer EL, and a second electrode CE that is a cathode electrode.

A plurality of first electrodes AE may be provided and spaced apart from each other on the second planarization layer 113, and a portion thereof may be exposed through an opening of the bank layer 114. The first electrode AE may be electrically connected to the connection electrode LE through a contact hole formed in the second planarization layer 113.

The first electrode AE may be disposed in the display area NA and the non-display area NA. The first electrode AE disposed in the non-display area NA may be electrically connected to the first metal layer 10 and the second metal layer 20. Here, the first metal layer 10 may be formed of the same material as the connection electrode LE, and the second metal layer 20 may be formed of the same material as the source electrode SE and the drain electrode DE, and may be electrically connected to the common power line VSS.

The light emitting layer EL may be disposed in each opening formed in the bank layer 114. Accordingly, the lower surface of the light emitting layer EL may contact the upper surface of the first electrode AE through the opening.

The second electrode CE may be disposed on the bank layer 114 and the first electrode AE. For example, the second electrode CE may be disposed in the display area NA and the non-display area NA.

The encapsulation layer 115 may be disposed on the second electrode CE. For example, the encapsulation layer 115 may include a first encapsulation layer 115a, a second encapsulation layer 115b, and a third encapsulation layer 115c.

The first encapsulation layer 115a may be formed of an inorganic material capable of low-temperature deposition, such as silicon nitride (SiNx), silicon oxide (SiOx), silicon oxynitride (SiON), aluminum oxide (Al₂O₃), or the like. When the first encapsulation layer 115a is deposited in a low-temperature atmosphere, the first encapsulation layer 115a may prevent the light emitting layer EL including the organic material vulnerable to the high-temperature atmosphere from being damaged during the deposition process.

The second encapsulation layer 115b may be disposed on the first encapsulation layer 115a. For example, the second encapsulation layer 115b may be formed of an organic insulating material such as acrylic resin, epoxy resin, polyimide, polyethylene, silicon oxycarbon (SiOC), etc. Since the second encapsulation layer 115b is formed of an organic material, it is possible to reduce step differences while sealing the underlying elements.

The third encapsulation layer 115c may be disposed on the second encapsulation layer 115b. For example, the third encapsulation layer 115c may be formed of an inorganic material such as silicon nitride (SiNx), silicon oxide (SiOx), silicon oxynitride (SiON), or aluminum oxide (Al₂O₃).

As described above, since the encapsulation layer 115 is formed of a plurality of layers, penetration of moisture or oxygen from the outside is minimized, thereby effectively protecting the light emitting element ED.

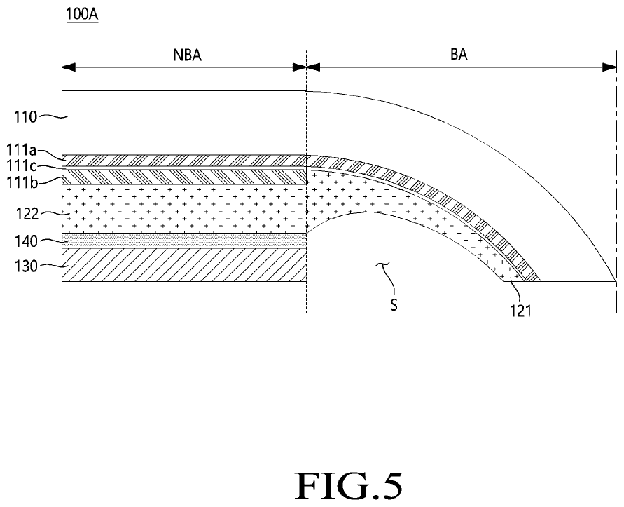

FIG. 5 is a view illustrating a bent state of a display device according to an embodiment of the disclosure.

Referring to FIG. 5, the display device 100A may further include a reinforcing portion 130 disposed under the support 120. For example, the reinforcing portion 130 may be fixed to a lower portion of the support 120 through an adhesive layer 140. In this case, the reinforcing portion 130 may overlap the second body portion 122. In other words, the reinforcing portion 130 may be disposed in a portion other than the bending area BA.

The reinforcing portion 130 may be formed of a metal material such as stainless steel (SUS) or a polymer material such as polymethyl methacrylate (PMMA), polycarbonate (PC), polyacrylate (PA), polyvinyl alcohol (PVA), acrylonitrile-butadiene-styrene (ABS), or polyethylene terephthalate (PET). When the reinforcing portion 130 is formed of a high rigid material such as SUS, it may have a high restoring force, so that the thickness of the reinforcing portion 130 may be decreased. Further, even when the thickness is decreased, the desired rigidity may be given to the reinforcing portion 130, so it may serve to support the display panel 110. Accordingly, the strength of the display panel 110 may be enhanced through the reinforcing portion 130 and the display panel 110 may be protected from an external impact.

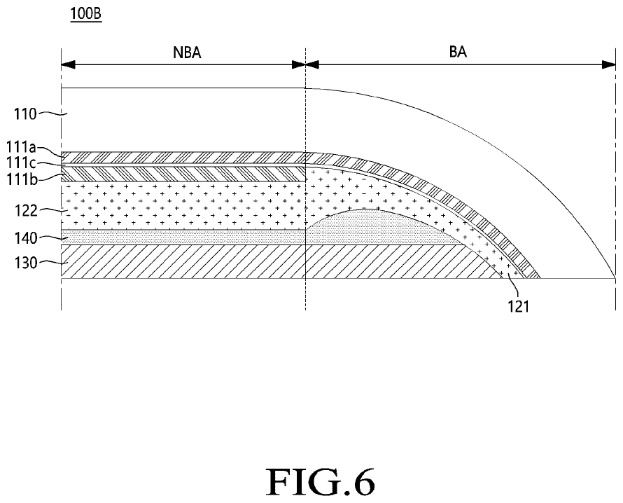

FIG. 6 is a view illustrating a bent state of a display device according to another embodiment of the disclosure. In this embodiment, the description focuses primarily on differences from the above-described embodiment.

Referring to FIG. 6, the display device 100B may include a reinforcing portion 130 disposed under the support 120. For example, the reinforcing portion 130 may be fixed to a lower portion of the support 120 through an adhesive layer 140. In this case, the reinforcing portion 130 may overlap the first body portion 121 and the second body portion 122. In other words, the reinforcing portion 130 may be disposed in both the bending area BA and the non-bending area NBA. In this case, since the entire lower side of the display panel 110 may be covered by the reinforcing portion 130, the strength of the display panel 110 may be further enhanced.

On the other hand, when the bending area BA is curved and bent, the display panel 110 may have an upwardly convex recess S formed in a lower portion of the first body portion 121 (see FIG. 5). Due to the recess portion S, an empty space may be created in the lower portion of the body portion 121, which may reduce the strength of the bending area BA. The adhesive layer 140 may be disposed in the recess S, reinforcing the bending area BA.

A reinforcing portion 130 may be disposed under the support structure 120 to further improve mechanical strength, particularly in the non-bending area NBA. The reinforcing portion 130 may overlap the second body portion 122 of the support structure 120 in a plan view (see FIGS. 5 and 6), and may optionally extend to overlap the first body portion 121 as well (see FIG. 6). In certain embodiments, when the display panel 110 is bent during operation, the reinforcing portion 130 may overlap both the first body portion 121 and the second body portion 122 in a cross-sectional view (see FIGS. 5 and 6). The support structure 120 and the reinforcing portion 130 together may define a stepped or contoured profile beneath the bending area BA. For example, due to the recessed or inclined lower portion of the first body portion and the varying overlap of the reinforcing portion, the combined structure may form a non-uniform thickness profile that supports bending while preserving the rigidity of surrounding regions. This configuration contributes to improved bendability, stress dispersion, and durability of the display device without sacrificing structural integrity.

Embodiments of the disclosure described above are briefly described below.

According to embodiments of the disclosure, there may be provided a display device comprising a display panel including a bending area and a non-bending area, and a support structure disposed at a lower portion of the display panel and supporting the lower portion of the display panel, the support structure including a first body portion overlapping the bending area and a second body portion overlapping the non-bending area, wherein a thickness of the first body portion is smaller than a thickness of the second body portion.

According to embodiments of the disclosure, the thickness of the first body portion may gradually decrease from the non-bending area toward the bending area.

According to embodiments of the disclosure, a lower portion of the first body portion may be formed in a concave curved shape toward the display panel.

According to embodiments of the disclosure, the first body portion adjacent to the second body portion may include an inclined surface. A slope of the inclined surface may be in a range of 30° to 90°.

According to embodiments of the disclosure, the display panel includes a first base substrate, and a second base substrate adjacent to the first base substrate, second base substrate being smaller than the first base substrate so that an end portion of the second base substrate is positioned inside the first base substrate.

According to embodiments of the disclosure, a thickness of an end portion of the first body portion may be equal to or less than a thickness of the second base substrate.

According to embodiments of the disclosure, the display panel may include a display area and a non-display area adjacent to the display area. An end portion of the first base substrate may overlap the non-display area, and an end portion of the second base substrate may overlap the display area.

According to embodiments of the disclosure, the bending area may include the non-display area and a portion of the display area adjacent to the non-display area.

According to embodiments of the disclosure, the display device may further comprise a reinforcing portion disposed under the support structure.

According to embodiments of the disclosure, the reinforcing portion may overlap the second body portion.

According to embodiments of the disclosure, the reinforcing portion may overlap the first body portion and the second body portion.

According to embodiments of the disclosure, the reinforcing portion may be fixed to the support structure by an adhesive layer. The adhesive layer may be disposed in a recess formed in a lower portion of the first body portion when the display panel is bent.

According to embodiments of the disclosure, the bending area may be formed on all edge portions of the display panel.

According to embodiments of the disclosure, the non-bending area may have a higher resolution than the bending area.

According to embodiments of the disclosure, there may be provided a display device comprising a display panel including a bending area and a non-bending area, and a support structure disposed at a lower portion of the display panel and supporting the lower portion of the display panel, the support structure including a first body portion overlapping the bending area and a second body portion overlapping the non-bending area, wherein the display panel includes a first base substrate, and a second base substrate adjacent to the first base substrate, the first base substrate extending from the non-bending area into the bending area beyond the second base substrate, such that an end portion of the second base substrate is positioned inward of an end portion of the first base substrate.

According to embodiments of the disclosure, a thickness of the first body portion may be smaller than a thickness of the second body portion.

According to embodiments of the disclosure, a lower portion of the first body portion may be formed in a concave curved shape toward the display panel.

According to embodiments of the disclosure, the display panel may include a display area and a non-display area adjacent to the display area. An end portion of the first base substrate may overlap the non-display area, and an end portion of the second base substrate may overlap the display area.

According to embodiments of the disclosure, the display device may further comprise a reinforcing portion disposed under the support and overlapping the second body portion.

According to embodiments of the disclosure, the display device may further comprise a reinforcing portion disposed under the support and overlapping the first body portion and the second body portion.

According to embodiments of the disclosure, a display device may comprise a display panel including a bending area and a non-bending area; and a support structure disposed under the display panel, the support structure including: a first body portion overlapping the bending area in a plan view, the first body portion having an upper portion and a lower portion opposite the upper portion, the upper portion facing the display panel; and a second body portion overlapping the non-bending area in a plan view. The lower portion of the first body portion may be recessed toward the display panel to form a bending space, such that the lower portion of the first body portion may have a reduced thickness relative to the second body portion in the bending area.

According to embodiments of the disclosure, the first body portion and the second body portion may be made of a same material.

According to embodiments of the disclosure, the thickness of the lower portion of the first body portion may gradually decrease from the non-bending area toward the bending area.

According to embodiments of the disclosure, the display panel may include a first base substrate and a second base substrate adjacent to the first base substrate, the second based substrate disposed between the first base substrate and the support structure. The first base substrate may extend from the non-bending area into the bending area beyond the second base substrate, such that an end portion of the second base substrate may be positioned inward of an end portion of the first base substrate.

According to embodiments of the disclosure, a thickness of the second base substrate may be equal to or greater than a thickness of the upper portion of the first body portion of the support structure.

According to embodiments of the disclosure, the lower portion of the first body portion may be concavely curved toward the display panel such that a thickness of the lower portion of the first body portion may be smaller than a thickness of the second body portion.

According to embodiments of the disclosure, the display may further comprise a reinforcing portion disposed under the support structure. The reinforcing portion may overlap the second body portion of the support structure at the non-bending area in a plan view.

According to embodiments of the disclosure, the reinforcing portion may further overlap the second body portion of the support structure at the bending area in a plan view.

According to embodiments of the disclosure, the reinforcing portion, when the display panel is bent during operation, may overlap both the first body portion and the second body portion in a cross-sectional view.

According to embodiments of the disclosure, the support structure and the reinforcing portion together may define either a stepped or contoured profile beneath the bending area.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel including a bending area and a non-bending area; and
a support structure disposed at a lower portion of the display panel and supporting the lower portion of the display panel, the support structure including a first body portion overlapping the bending area and a second body portion overlapping the non-bending area,
wherein a thickness of the first body portion is smaller than a thickness of the second body portion.

2. The display device of claim 1, wherein the thickness of the first body portion gradually decreases from the non-bending area toward the bending area.

3. The display device of claim 1, wherein a lower portion of the first body portion is formed in a concave curved shape toward the display panel.

4. The display device of claim 1, wherein the first body portion adjacent to the second body portion includes an inclined surface, and wherein a slope of the inclined surface is in a range of 30° to 90°.

5. The display device of claim 1, wherein the display panel includes a first base substrate, and a second base substrate adjacent to the first base substrate, the second base substrate being smaller than the first base substrate so that an end portion of the second base substrate is positioned inside the first base substrate.

6. The display device of claim 5, wherein a thickness of an end portion of the first body portion is equal to or less than a thickness of the second base substrate.

7. The display device of claim 5, wherein the display panel includes a display area and a non-display area adjacent to the display area, and
wherein an end portion of the first base substrate overlaps the non-display area, and an end portion of the second base substrate overlaps the display area.

8. The display device of claim 7, wherein the bending area includes the non-display area and a portion of the display area adjacent to the non-display area.

9. The display device of claim 1, further comprising a reinforcing portion disposed under the support structure.

10. The display device of claim 9, wherein the reinforcing portion overlaps the second body portion.

11. The display device of claim 9, wherein the reinforcing portion overlaps the first body portion and the second body portion.

12. The display device of claim 11, further comprising an adhesive layer, wherein the reinforcing portion is fixed to the support structure by the adhesive layer, and wherein the adhesive layer is disposed in a recess formed in a lower portion of the first body portion when the display panel is bent.

13. The display device of claim 1, wherein the bending area is formed on all edge portions of the display panel.

14. The display device of claim 1, wherein the non-bending area has a higher resolution than the bending area.

15. A display device, comprising:
a display panel including a bending area and a non-bending area; and
a support structure disposed at a lower portion of the display panel and supporting the lower portion of the display panel, the support structure including a first body portion overlapping the bending area and a second body portion overlapping the non-bending area,
wherein the display panel includes a first base substrate, and a second base substrate adjacent to the first base substrate, the first base substrate extending from the non-bending area into the bending area beyond the second base substrate, such that an end portion of the second base substrate is positioned inward of an end portion of the first base substrate.

16. The display device of claim 15, wherein the display panel includes a display area and a non-display area adjacent to the display area, and
wherein an end portion of the first base substrate overlaps the non-display area, and an end portion of the second base substrate overlaps the display area.

17. A display device comprising:
a display panel including a bending area and a non-bending area; and
a support structure disposed under the display panel, the support structure including:
a first body portion overlapping the bending area in a plan view, the first body portion having an upper portion and a lower portion opposite the upper portion, the upper portion facing the display panel; and
a second body portion overlapping the non-bending area in a plan view,
wherein the lower portion of the first body portion is recessed toward the display panel to form a bending space, such that the lower portion of the first body portion has a reduced thickness relative to the second body portion in the bending area.

18. The display device of claim 17, wherein the first body portion and the second body portion are made of a same material.

19. The display device of claim 17, wherein the thickness of the lower portion of the first body portion gradually decreases from the non-bending area toward the bending area.

20. The display device of claim 17, wherein the display panel includes a first base substrate and a second base substrate adjacent to the first base substrate, the second based substrate disposed between the first base substrate and the support structure, and
wherein the first base substrate extends from the non-bending area into the bending area beyond the second base substrate, such that an end portion of the second base substrate is positioned inward of an end portion of the first base substrate.
